(19) United States
(12) Patent Application Publication
(10) Pub. No.: US 2025/0150064 A1
(43) Pub. Date: May 8, 2025

(54) MULTIPHASE CHAOTIC SYNCHRONIZATION SYSTEM

(71) Applicant: 15626200 CANADA INC., Rawdon (CA)

(72) Inventors: Eric MORIN, Longueuil (CA); Emmanuel ZANRE, Longueuil (CA)

(21) Appl. No.: 18/941,145

(22) Filed: Nov. 8, 2024

Related U.S. Application Data
(60) Provisional application No. 63/547,762, filed on Nov. 8, 2023.

(51) Int. Cl. H03K 3/356; H03K 3/84

(52) U.S. Cl. CPC H03K 3/356095; H03K 3/84

(57) ABSTRACT

A system for multiphase chaotic synchronization comprises a processor and a non-transitory computer-readable medium having stored thereon program instructions executable by the processor for receiving, from a synchronization source coupled to an input of the processor, a synchronization signal having a synchronization phase and a synchronization frequency associated therewith, generating, based on the synchronization signal, at least three periodic signals each having a frequency corresponding to the synchronization frequency, and a phase determined based on the synchronization phase, and outputting each of the at least three periodic signals to a respective one of at least three chaotic circuits for use in controlling an operation of at least one electronic device electrically coupled to the at least three chaotic circuits.

### CROSS REFERENCE TO RELATED APPLICATIONS

The present application claims the benefit of U.S. Provisional Patent Application No. 63/547,762 filed on Nov. 8, 2023, the contents of which are hereby incorporated by reference.

### TECHNICAL FIELD

The present disclosure relates generally to chaotic circuitry, and particularly to a multiphase synchronization system using chaotic circuitry.

### BACKGROUND OF THE ART

The chaotic nature of a CHUA circuit implies that the condition of the circuit cannot, in practical terms, be predicted. This behavior can be exploited in systems needing a source of pseudo-random signals. While the need for pseudo-random signals is present in various fields, the variety of implementation of CHUA circuits is, however, limited due to the chaotic nature thereof.

Improvements to the technology led to the phase modulation of CHUA circuits by providing a modulation signal to the CHUA circuit. Such phase-modulated CHUA circuits have various implementations in communication systems, but are limited to single phased-modulated chaotic signals. Implementations in which multiple phased-modulated chaotic signals are synchronized together are, however, still lacking. Therefore, improvements are needed.

### SUMMARY

In accordance with one aspect, there is provided a system for multiphase chaotic synchronization. The system comprises a processor and a non-transitory computer-readable medium having stored thereon program instructions executable by the processor for receiving, from a synchronization source coupled to an input of the processor, a synchronization signal having a synchronization phase and a synchronization frequency associated therewith, generating, based on the synchronization signal, at least three periodic signals each having a frequency corresponding to the synchronization frequency, and a phase determined based on the synchronization phase, and outputting each of the at least three periodic signals to a respective one of at least three chaotic circuits for use in controlling an operation of at least one electronic device electrically coupled to the at least three chaotic circuits.

In accordance with another aspect, there is provided a method for multiphase chaotic synchronization. The method comprising at a computing device receiving a synchronization signal having a synchronization phase and a synchronization frequency associated therewith, generating, based on the synchronization signal, at least three periodic signals each having a frequency corresponding to the synchronization frequency, and a phase determined based on the synchronization phase, and outputting each of the at least three periodic signals to a respective one of at least three chaotic circuits for use in controlling an operation of at least one electronic device electrically coupled to the at least three chaotic circuits.

In accordance with yet another aspect, there is provided a system for multiphase chaotic synchronization. The system comprising a register configured to generate a plurality of phase truncated bits, a phase converter coupled to the register and configured to receive therefrom the plurality of phase truncated bits and to map the plurality of phase truncated bits to a plurality of digital amplitude values, and a digital-to-analog converter coupled to the phase converter and configured to receive therefrom the plurality of digital amplitude values and to generate, based on the plurality of digital amplitude values, a periodic signal to be provided to a respective one of at least three chaotic circuits for use in controlling an operation of at least one electronic device electrically coupled to the at least three chaotic circuits.

### BRIEF DESCRIPTION OF THE DRAWINGS

Reference is now made to the accompanying figures in which:

FIG. 1 is a block diagram of an example embodiment of a system for multiphase chaotic synchronization;

FIGS. 2A and 2B are schematic diagrams of an example embodiment of the system of FIG. 1;

FIG. 3 is a graph showing a three-phase signal generated by the system of FIG. 1, in accordance with an embodiment;

FIG. 4 is a schematic diagram of another example embodiment of the system of FIG. 1;

FIG. 5 is a block diagram of an example embodiment of a source of signals using direct digital frequency synthesizer;

FIG. 6 is a flowchart of an example method for multiphase chaotic synchronization using the system of FIG. 1; and

FIG. 7 is a block diagram of an example computing device, in accordance with an illustrative embodiment.

It will be noted that throughout the appended drawings, like features are identified by like reference numerals.

### DETAILED DESCRIPTION

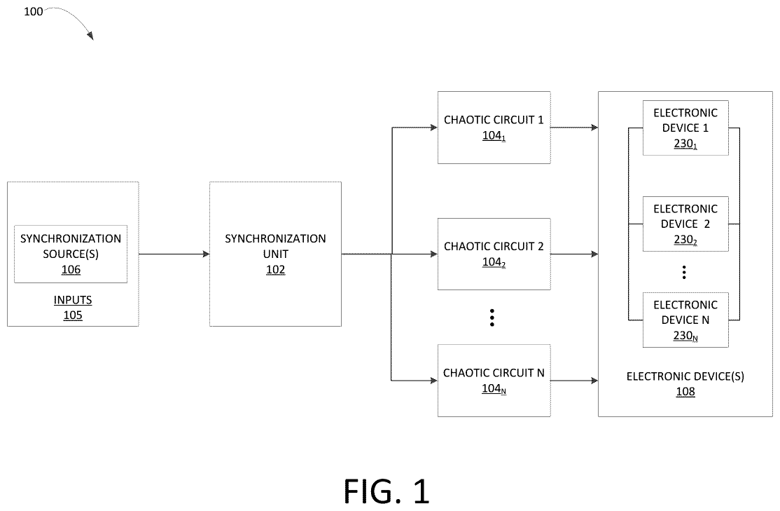

Referring now to FIG. 1, a system 100 for multiphase chaotic synchronization will now be described, in accordance with one embodiment. As used herein, the terms “chaos” and “chaotic”, when used in reference to a dynamic system, refer to the fact that the state of the system after an arbitrary time period cannot be predicted. A CHUA circuit is the simplest electrical circuit exhibiting chaotic behaviour. The CHUA circuit is a nonperiodic oscillator which produces an oscillating waveform that is aperiodic (i.e. never repeats). As will be described further below, it is proposed herein to use a programmable frequency and phase oscillator to achieve multi-phase synchronization in the system 100 and ensure that the signals generated by the system 100 remain synchronized in frequency and in phase. As used herein, the terms “synchronization”, “synchronize”, or “synchronized”, refers to the fact that electrical and/or electronic components (e.g., the chaotic circuits or electronic equipment coupled thereto) can be controlled so that their common signals have identical behavior and the operation of the components tends to converge over time. The system 100 may be used in a variety of applications for controlling the operation of various electrical and/or electronic equipment (or components) that are connected in parallel. Any suitable electrical and/or electronic equipment (e.g., power inverters, power supply, motor control, motor driver, boost circuits including, but not limited to, boost converters and inverting buck-boost converters, or other devices) requiring multiphase change may apply.

The system 100 comprises a synchronization unit 102 which, as will be described further below, is configured to generate a plurality of (N) waveforms or periodic wave signals (e.g., sinusoidal signals or sinewaves) each having a given output phase, and to output a respective wave signal to each of a plurality of (N) chaotic circuits 104₁, 104₂, . . . , 104_{N} used to control the operation of electronic equipment (illustrated as electronic device(s) 108) coupled thereto. In one embodiment, multiple electronic devices 108 are electronically connected in parallel and the chaotic circuits are configured to output signals that cause the electronic devices 108 to be synchronized with one another. The signals provided by the chaotic circuits further enable the electronic devices 108 to operate as multi-phase systems. Any suitable number (N) of chaotic circuits 104₁, 104₂, . . . , 104_{N} may apply. In one embodiment, the system 100 comprises three (3) chaotic circuits 104₁, 104₂, . . . , 104_{N}, such that three (3) wave signals are generated by the synchronization unit 102 (e.g., for use on electronic device(s) 108 comprising a three-phase power section, i.e. a three-phase system). It should however be understood that the system 100 may comprise more than three (3) chaotic circuits 104₁, 104₂, . . . , 104_{N}, such that the synchronization unit may generate more than three (3) wave signals for use in electronic device(s) 108 comprising multiphase systems (e.g., systems having six (6) phases, twelve (12) phases, twenty-four phases (24), or any other suitable number of phases).

As will be described further below, the synchronization unit 102 is configured to receive data from a plurality of inputs 105 for use in generating the wave signals. Although multiple inputs 105 are illustrated and described herein, it should be understood that, in some embodiments, the synchronization unit 102 may be configured to receive data from a single input. In one embodiment, the inputs 105 comprise one or more synchronization sources 106 to which the synchronization unit 102 can be synchronized.

While a single synchronization unit 102 is illustrated and described herein, it should be understood that the system 100 may comprise a plurality of interconnected synchronization units 102 configured to cooperate with one another to achieve the desired synchronization for the system 100.

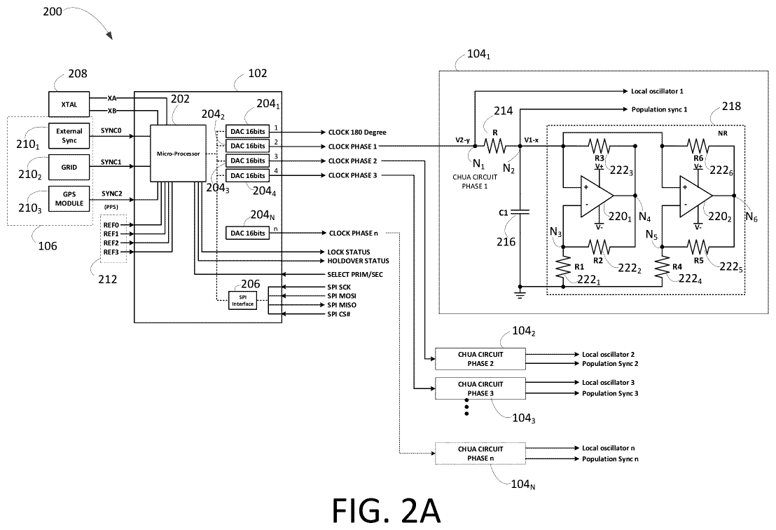

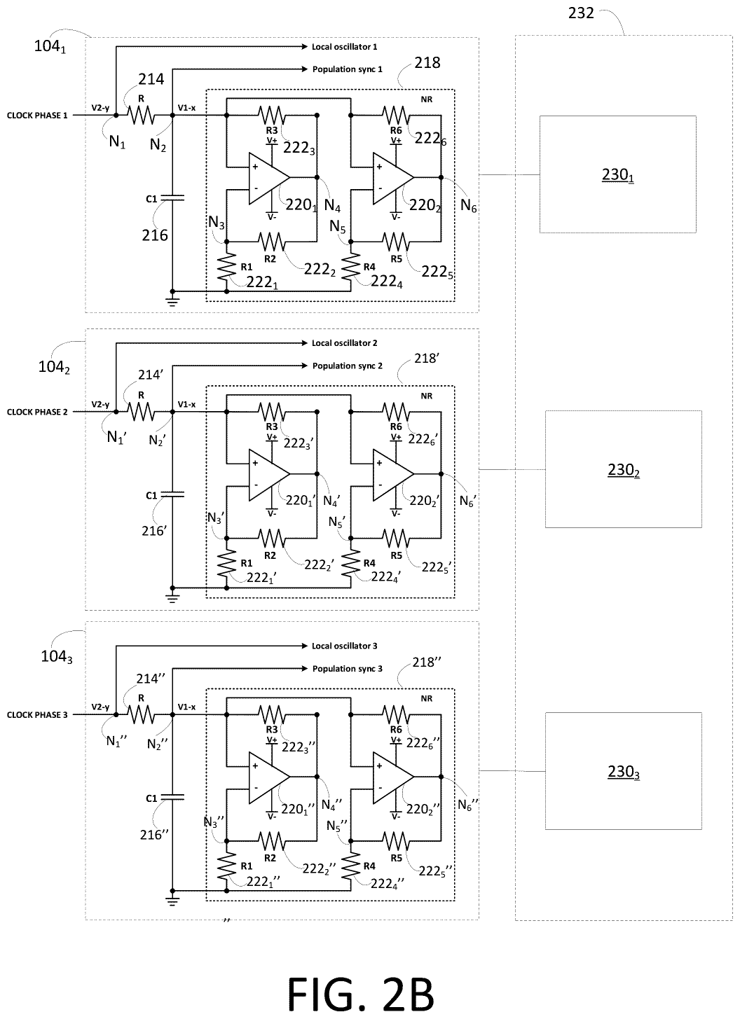

Referring now to FIG. 2A in addition to FIG. 1, a first embodiment 200 of the multiphase chaotic synchronization system 100 of FIG. 1 will now be described. The synchronization unit 102 comprises a processing unit 202 (illustrated as a micro-processor), a plurality (N) of 16-bit digital-to-analog converters (DAC) 204₁, 204₂, . . . , 204_{N}, and a Serial Peripheral Interface (SPI) 206. The number (N) of DACs 204₁, 204₂, . . . , 204_{N} illustratively matches the number of chaotic circuits 104₁, 104₂, . . . , 104_{N} and at least three DACs 204₁, 204₂, . . . , 204_{N} are provided. In some embodiments, the synchronization unit 102 comprises a plurality of processing units 202, which may be beneficial to create redundancy in the generated signals.

In the illustrated embodiment, the inputs (reference 105 in FIG. 1) provided to the synchronization unit 102 comprise an oscillator input 208, to which a periodic, oscillating or alternating current (AC) signal (also referred to herein as a “reference signal”) is provided. The reference signal is a stable clock signal that is used by the synchronization unit 102 as a reference for the generation of clock signals that serve for the synchronization unit's internal timing and control mechanisms. The reference signal may be provided, via the oscillator input 208, by any suitable oscillator (not shown) coupled to the processing unit 202. The oscillator may include, but is not limited to, a crystal oscillator (e.g., an Oven-Controlled Crystal Oscillator or OCXO, a Temperature-Compensated Crystal Oscillator or TCXO, or the like). In some cases, the oscillator input 208 has a temperature coefficient ranging from about 50 ppm/° C. to about 100 ppm/° C. Generally, the signal provided at the oscillator input 208 is configured to have a frequency that matches (i.e. corresponds to) that of the synchronization unit 102.

The inputs 105 provided to the synchronization unit 102 further comprise an input (referred to herein as a “synchronization signal”) received from synchronization source(s) 106 coupled to the processing unit 202. The synchronization source(s) 106 include, in the illustrated embodiment, an external synchronization source 210₁ (i.e. external to the synchronization unit 102 and remote therefrom), a grid synchronization source 210₂ associated with the power utility network (or electrical grid), such as a 60 Hz power utility network with 1 ppm precision, and a Global Positioning System (GPS) module synchronization source 210₃ (e.g., a GPS receiver or other pulse per second (PPS) signal generator, the PPS signal being an electrical signal that specifies the start of a second and having a precision greater than about 1 ppm). In some embodiments, the external synchronization source 210₁ is an atomic clock, including, but not limited to, a cesium atomic clock, a rubidium atomic clock, an optical lattice clock, and the like. The use of an atomic clock may increase the precision of the synchronization unit 102. In some embodiments, the atomic clock may provide a synchronization signal having a precision between about 10⁻³ ppm and about 10⁻¹⁸ ppm. In other embodiments, the inputs 105 provided to the synchronization unit 102 comprise a high precision signal obtained from a utility provider. It will be appreciated that the nature of the inputs 105 may vary depending on the application. Other embodiments may therefore apply.

The processing unit 202 is configured to implement a selection algorithm (e.g., execute a holdover function) in order to select, among the synchronization source(s) 106, at least one synchronization source to be tracked to generate wave signals at the output of the synchronization unit 102. It should be understood that, in some embodiments, a single synchronization source is selected and used to generate all wave signals. The selection algorithm may be implemented based on a selection input (labelled “Select Prim/Sec” in FIG. 2A) and on a plurality of reference inputs 212, which may be provided to the processing unit 202 to indicate the synchronization source to be selected among the synchronization source(s) 106. In some embodiments, the reference inputs 212 allow the processing unit 202 to choose the number of sources (among the synchronization source(s) 106) to be used for synchronization purposes, as well as to indicate a default configuration.

For example, the first reference input labelled “REF0” in FIG. 2A may be associated with the oscillator input 208, such that the oscillator input 208 is used for synchronization purposes when the “REF0” input is set to a first value (e.g., logical ‘1’ or ‘True’), and not used otherwise (when the “REF0” input is set to a second value, e.g., logical ‘0’ or ‘False’). Similarly, the second reference input labelled “REF1” in FIG. 2A may be associated with the external synchronization source 210₁, such that the external synchronization source 210₁ is used for synchronization purposes when the “REF1” input is set to a first value (e.g., logical ‘1’ or ‘True’), and not used otherwise (when the “REF1” input is set to a second value, e.g., logical ‘0’ or ‘False’). The third reference input labelled “REF2” in FIG. 2A may be associated with the grid synchronization source 210₂, such that the grid synchronization source 210₂ is used for synchronization purposes when the “REF2” input is set to a first value (e.g., logical ‘1’ or ‘True’), and not used otherwise (when the “REF2” input is set to a second value, e.g., logical ‘0’ or ‘False’). The fourth reference input labelled “REF3” in FIG. 2A may be associated with the GPS module synchronization source 210₃, such that the GPS module synchronization source 210₃ is used for synchronization purposes when the “REF3” input is set to a first value (e.g., logical ‘1’ or ‘True’), and not used otherwise (when the “REF3” input is set to a second value, e.g., logical ‘0’ or ‘False’).

In some embodiments, the reference inputs 212 may be implemented using physical connections, e.g. one or more pull-up resistors. In other embodiments, the processing unit 202 may be configured to implement the selection algorithm via a signal high lever and/or the SPI 206. Other embodiments may apply.

The processing unit 202 may also be configured to output a holdover status (labelled “Holdover status” in FIG. 2A), as will be discussed further below. Once the appropriate synchronization source (i.e. any one of the external synchronization source 210₁, the power utility network via grid synchronization source 210₂, and the GPS module synchronization source 210₃) has been selected, the processing unit 102 is configured to synchronize with the synchronization source and generate wave signals having a frequency and phase that match (i.e. correspond to) the frequency and phase (referred to herein as “synchronization frequency” and “synchronization phase”) of the synchronization signal received from the selected synchronization source. In some embodiments, to enable redundancy, the external synchronization source 210₁ may be another multiphase chaotic synchronization system as in 100. In some cases, using the grid synchronization source 210₂, synchronization may be achieved based on the frequency of a voltage generated using an isolation transformer and high voltage isolation. In one embodiment, the external synchronization source 210₁ is the primary source of synchronization, followed by the grid synchronization source 210₂ as the secondary source of synchronization (i.e. in case of failure of the primary one), and the GPS module synchronization source 210₃ as the third source of synchronization (i.e. in case of failure of the first and secondary ones). In some embodiments, if the synchronization signal received from the synchronization source(s) 106 is lost, disconnected, or unavailable (i.e. if failure of all synchronization sources 106 is detected), the signal provided by the oscillator input 208 (i.e. the reference signal) may be used as a reference clock (i.e. as the synchronization signal) to control the overall system 100.

In order to generate wave signals (e.g., sinewaves) to be sent to the chaotic circuits 104₁, 104₂, . . . , 104_{N}, the processing unit 202 is further configured to access (e.g., retrieve from memory, at least one database, or any other suitable storage accessible to the processing unit 202, or obtain via any other suitable manner) a lookup table that contains digital amplitude information (i.e. digital amplitude values) for one or more complete cycles of a sinewave (or other periodic waveform or signal). Each address in the lookup table corresponds to a digital amplitude value on the periodic signal. By addressing the lookup table, the processing unit 202 correlates the input data received at the inputs 105 (e.g., the synchronization signal) with the digital amplitude information from the lookup table to map the input data into a digital amplitude. In particular, the processing unit 202 queries the lookup table to determine the digital amplitude values that are to be used to generate each wave signal having a frequency and phase corresponding to those of the synchronization signal. Periodic wave signals having the digital amplitude values associated therewith are then generated based on the querying. Although reference is made herein to a lookup table being used to determine amplitude information for generating wave signals, it should be understood that the possible digital amplitude values for the wave signals may be presented in any suitable format other than a lookup table. Furthermore, it will be appreciated that the shape of the signal may be established based on the amplitude values obtained from the lookup table, such that the variation of the amplitude values in time correlates to any suitable periodic shape including, but not limited to, a sinusoidal shape, a square shape, and a triangular shape.

Once the digital amplitude information is determined, the processing unit 202 sends this digital information to the DACs 204₁, 204₂, . . . , 204_{N} which are configured to generate the wave signals based on the digital amplitude information (i.e. to convert the digital amplitude information into at least three analog signals having the amplitude values associated therewith). Using the systems and methods described herein, it is thus possible to adjust the amplitude, frequency, and phase of the wave signals that are generated using the synchronization unit 102 on demand, which in turn may improve the stability and flexibility of the system 100.

While reference is made herein to sinusoidal signals (i.e. sinewaves) being generated by the synchronization unit 102, it should be understood that any other suitable arbitrary waveform, including, but not limited to, a square wave or a triangular (e.g., sawtooth or ramp) wave (e.g., for boost circuit applications), may apply. The output of each DAC 204₁, 204₂, . . . , 204_{N} (e.g., sinusoidal signals labelled “Clock Phase 1”, “Clock Phase 2”, “Clock Phase 3”, . . . , “Clock Phase n” in FIG. 2A) is then provided as input to a respective chaotic circuit 104₁, 104₂, . . . , 104_{N}.

In one embodiment, the wave signals generated by the synchronization unit 102 are used to control the operation of the chaotic circuits 104₁, 104₂, . . . , 104_{N} for split phase power applications or any other suitable application. In this case, the plurality of wave signals are out of phase by a predetermined phase shift amount (or angle), causing the chaotic circuits 104₁, 104₂, . . . , 104_{N} to be in a phase shift mode. In particular, one of the wave signals has a phase corresponding to the synchronization phase and the remaining wave signals have a phase that is shifted relative to the synchronization phase and relative to the phase of other signals. The phase shift amount may vary depending on the application and any suitable phase shift amount (e.g., 60 degrees, 120 degrees, 180 degrees, or the like) may apply. It should however be understood that, in other embodiments, the plurality of wave signals may have the same phase (which corresponds to the synchronization phase). In some embodiments, the synchronization unit 102 generates sinusoidal signals with a precision (i.e. frequency of oscillator change) of about 1×10⁻⁶ Hz, which is significantly lower than the typical variation of about 0.1 Hz exhibited by conventional 60 Hz implementations.

In some embodiments, the processing unit 202 may be configured to implement a voltage monitoring and compensation feature to maintain the stability of the system 100 with temperature variation. Indeed, the stability of chaotic circuits (e.g., CHUA circuits) as in 104₁, 104₂, . . . , 104_{N} decreases with changes in temperature. The processing unit 202 may be configured to use any suitable technique to compensate for changes in temperature and thus maintain the stability of synchronization.

In some embodiments, the processing unit 202 is further configured to output a lock status indicative of a synchronization (i.e. in-sync or out-of-sync) status of the outputs of the processing unit 202. In one embodiment, the processing unit 202 is configured to output a lock status signal having a first value (e.g., logical ‘1’ or ‘True’) when the processing unit's outputs (i.e. the outputs of the DAC 204₁, 204₂, . . . , 204_{N}) are synchronized, and to output a lock status signal having a second value (e.g., logical ‘0’ or ‘False’) when the outputs are not synchronized.

In some embodiments, the processing unit 202 is further configured to output the holdover status indicative of a change in the inputs provided by the synchronization sources 106. In particular, the holdover status will indicate if the signal provided by any one of the external synchronization source 210₁, the power utility network via grid synchronization source 210₂, and the GPS module synchronization source 210₃ is failing, disconnected or lost. For example, the holdover status may be set to a first value (e.g., logical ‘1’ or ‘True’) when all synchronization sources 106 are operational and a second value (e.g., logical ‘0’ or ‘False’) when one or more of the synchronization sources 106 is not operational (e.g., failing, disconnected or lost). The processing unit 202 may be configured to select a synchronization source 106 based on the holdover status. For example, when the holdover status is logical ‘0’ or ‘False’, the processing unit 202 may be configured to use the signal from the oscillator input 208 (rather than the signal from one of the synchronization sources 106 which is used when the holdover status is logical ‘1’ or ‘True’) for synchronization purposes. In some cases, the lock status and the holdover status are provided to output ports. The lock status and the holdover status may also be provided to the SPI 206.

As understood by those skilled in the art, a chaotic circuit typically comprises an oscillator portion electrically connected to a chaotic portion. In the embodiment of FIG. 2A, the synchronization unit 102 replaces the oscillator portion of each chaotic circuit 104₁, 104₂, . . . , 104_{N}, such that each chaotic circuit 104₁, 104₂, . . . , 104_{N} only comprises a chaotic portion to which the synchronization unit 102 is configured to be electrically coupled. In particular, the multiphase output of the synchronization unit 102 is connected to the impedance matching resistor and capacitor of each chaotic circuit 104₁, 104₂, . . . , 104_{N}. The synchronization unit 102 then operates as a programmable frequency and phase oscillator that is configured to adjust a phase and a frequency of the circuit oscillations generated at an output of the system 100 (i.e. of the signals output by the chaotic circuits 104₁, 104₂, . . . , 104_{N}).

As can be seen in FIG. 2A, each chaotic circuit as in 104₁ (i.e. the chaotic portion thereof) comprises a linear resistor 214 having a resistance R and connected between nodes N₁ and N₂, a capacitor 216 having capacitance C1 and connected in series with the resistor 214, between node N₂ and ground, and a negative nonlinear resistor circuit 218 connected in parallel with the capacitor 216, between node N₂ and ground. The resistor 214 and the capacitor 216 are referred to herein as the impedance matching resistor and capacitor of the chaotic circuit as in 104₁. The negative nonlinear resistor circuit 218 comprises a first operational amplifier 220₁ and a second operational amplifier 2202 and six (6) resistors 222₁, 222₂, 222₃, 222₄, 222₅, 222₆. The non-inverting input of the first operational amplifier 220₁ is connected to node N₂, its inverting input is connected to a node N₃, and its output is connected to a node N₄. A first resistor 222₁ having a resistance R1 is connected between node N₃ and ground, a second resistor 222₂ having a resistance R2 is connected between nodes N₃ and N₄, and a third resistor 222₃ having a resistance R3 is connected between nodes N₂ and N₄. Similarly, the non-inverting input of the second operational amplifier 220₂ is connected to node N₂, its inverting input is connected to a node N₅, and its output is connected to a node N₆. A fourth resistor 222₄ having a resistance R4 is connected between node N₅ and ground, a fifth resistor 222₅ having a resistance R5 is connected between nodes N₅ and N₆, and a sixth resistor 222₆ having a resistance R6 is connected between nodes N₂ and N₆.

It should be understood that all chaotic circuits 104₁, 104₂, . . . , 104_{N} have a similar configuration. For sake of simplicity and clarity, only components of chaotic circuit 104₁ are therefore shown in FIG. 2A. FIG. 2B however details the components of each chaotic circuit 104₁, 104₂, 104₃. It can be seen from FIGS. 2A and 2B that the synchronization unit 102 is connected to each chaotic circuit 104₁, 104₂, . . . , 104_{N} at the same respective node (labelled node N₁ for chaotic circuit 104₁, node N_{1′} for chaotic circuit 104₂, and node N_{1″} for chaotic circuit 104₃) and supplies a sinusoidal signal (labelled “Clock Phase 1”, “Clock Phase 2”, “Clock Phase 3”, . . . , “Clock Phase n” in FIG. 2A) to each chaotic circuit 104₁, 104₂, . . . , 104_{N} via this node N₁, N_{1′}, N_{1″}.

In one embodiment, each chaotic circuit 104₁, 104₂, . . . , 104_{N} is configured to generate, based on the signals (e.g., the sinusoidal signals “Clock Phase 1”, “Clock Phase 2”, “Clock Phase 3”, . . . , “Clock Phase n”) received from the synchronization unit 102, control signals comprising a local oscillator signal (labelled “Local oscillator 1”, “Local oscillator 2”, “Local oscillator 3” for chaotic circuits 104₁, 104₂, and 104₃, respectively) and a population synchronization signal (labelled “Population sync 1”, “Population sync 2”, “Population sync 3” for chaotic circuits 104₁, 104₂, and 104₃, respectively). The local oscillator signals and the population synchronization signals are in turn output to the electronic device(s) 108 coupled to the chaotic circuits 104₁, 104₂, . . . , 104_{N}. In one embodiment, the number of electronic devices 108 matches the number of chaotic circuits 104₁, 104₂, . . . , 104_{N} such that each chaotic circuit 104₁, 104₂, . . . , 104_{N} is coupled to a given electronic device 108 and provides its respective local oscillator signal and the population synchronization signal thereto. In particular, the local oscillator signals are provided to the control loop of the electronic equipment (i.e., the electronic device(s) 108 in FIG. 1) coupled the chaotic circuits 104₁, 104₂, . . . , 104_{N}. Using the local oscillator signals, operation of the electronic device(s) 108 can thus be controlled externally via the chaotic circuits 104₁, 104₂, . . . , 104_{N} (rather than internally within the electronic device(s) 108).

The population synchronization signals are also provided to the various electronic equipment for synchronization thereof. The population synchronization signals indeed serve as virtual master-slave signals that allow to synchronize the voltage and frequency of multiple electronic components, such as multiple electronic devices (labelled 230₁, 230₂, 230_{N}, . . . , 230_{N} in FIG. 1 and FIG. 2B) which are electrically connected in parallel (e.g., to form a multi-phase system labelled 232 in FIG. 2B) and coupled to the output of the chaotic circuits 104₁, 104₂, . . . , 104_{N}. Using the population synchronization signals may allow to add and/or remove electronic device(s) 108 from the system 100 without affecting the synchronization of the electronic device(s) 108. Indeed, when a new electronic device 108 is added to the system 100 (i.e. coupled to a chaotic circuit 104₁, 104₂, . . . , 104_{N}), the new electronic device 108 can automatically synchronize with the other electronic devices 108 upon receipt of the population synchronization signal from the chaotic circuit 104₁, 104₂, . . . , 104_{N} coupled to the new electronic device 108. Similarly, when an electronic device 108 is removed from the system 100 (i.e. uncoupled from its respective chaotic circuit 104₁, 104₂, . . . , 104_{N}), the remaining electronic device(s) 108 remain synchronized with one another based on the population synchronization signals received from their respective chaotic circuit 104₁, 104₂, . . . , 104_{N}.

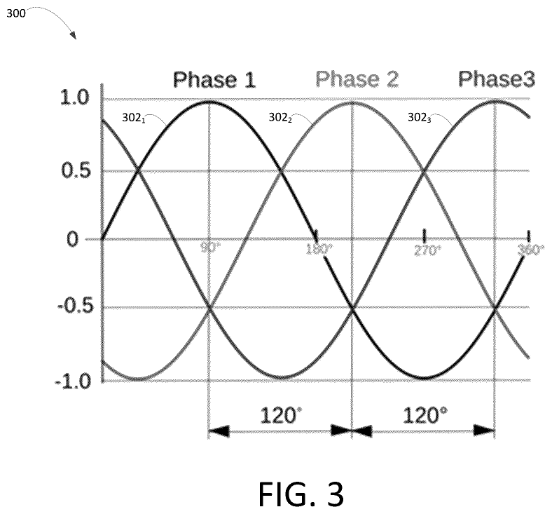

FIG. 3 shows a graph 300 of a three-phase signal generated by the synchronization unit 102, in accordance with one embodiment. As can be seen from FIG. 3, the three-phase signal comprises a first sine wave 302₁ having a first phase (labelled “Phase 1” in FIG. 3), a second sine wave 302₂ having a second phase (labelled “Phase 2” in FIG. 3), and a third sine wave 302₃ having a third phase (labelled “Phase 3” in FIG. 3). In the embodiment of FIG. 3, the first, second, and third phases are offset by 120 degrees. Other embodiments may apply. While FIG. 3 illustrates a three-phase signal, it should be understood that the synchronization unit 102 may generate any suitable multi-phase signal having more than three (3) phases, as described herein above. As such, the signal generated by the synchronization unit may comprise more than three (3) sine waves as in 302₁, 302₂, and 302₃.

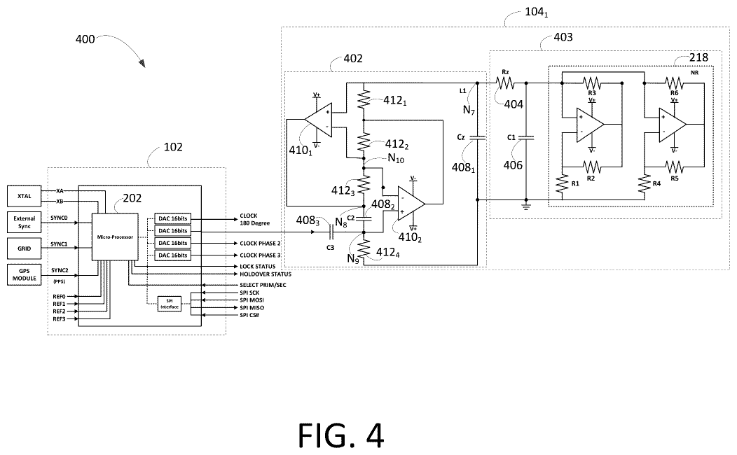

Referring now to FIG. 4 in addition to FIG. 1, a second embodiment 400 of the multiphase chaotic synchronization system 100 of FIG. 1 will now be described. In the embodiment of FIG. 4, each chaotic circuit 104₁, 104₂, . . . , 104_{N} comprises both an oscillator portion 402 and a chaotic portion 403 connected to the oscillator portion 402, and the synchronization unit 102 is configured to be electrically coupled to the oscillator portion 402 of each chaotic circuit 104₁, 104₂, . . . , 104_{N} in order to achieve redundancy. The chaotic portion 403 is similar to that described above with reference to FIG. 2A and comprises a linear resistor 404 having a resistance Rz, a capacitor 406 having capacitance C1 and connected in series with the resistor 404, and a negative nonlinear resistor circuit 218 connected in parallel with the capacitor 406. The negative nonlinear resistor circuit 218 is as described above with reference to FIG. 2A and comprises similar components.

In the embodiment of FIG. 4, the oscillator portion 402 comprises a first capacitor 408₁ having a capacitance Cz and connected in parallel with the capacitor 406, between a node N₇ and ground, a second capacitor 408₂ having a capacitance C2 and connected between a node N₈ and a node N₉, and a third capacitor 408₃ having a capacitance C3 and connected between node N₉ and an output of the synchronization unit 102. The synchronization unit 102 is electrically coupled to the oscillator portion 402 through the capacitor 408₃ at node N₉ in order to stabilize and balance the oscillator portion 402 and make the output signal provided at node N₇ in phase with the synchronization unit 102. In addition, electrically coupling the synchronization unit 102 at node N₉ via the capacitor 408₃ prevents inversion of the signal provided at node N₇ relative to the source signal coming from the synchronization unit 102.

The oscillator portion 402 further comprises a first operational amplifier 410₁, a second operational amplifier 410₂, and four (4) resistors 412₁, 412₂, 412₃, 412₄. The capacitors 408₂, 408₃, the operational amplifiers 410₁, 410₂, and the resistors 412₁, 412₂, 412₃, 412₄ form a gyrator circuit (not shown). The non-inverting input of the first operational amplifier 410₁ is connected to node N₇, its inverting input (and that of the second operational amplifier 410₂) is connected to a node N₁₀, and its output is connected to node N₈. A first resistor 412₁ is connected between node N₇ (i.e. to the non-inverting input of the first operational amplifier 410₁) and an output of the second operational amplifier 410₂. A second resistor 412₂ is connected between the output of the second operational amplifier 410₂ and node N₁₀ (i.e. to the inverting inputs of the first and second operational amplifiers 410₁, 410₂). A third resistor 412₃ is connected between node N₁₀ (i.e. the inverting inputs of the first and second operational amplifiers 410₁, 410₂) and node N₈ (i.e. the output of the first operational amplifier 410₁). A fourth resistor is 412₄ is connected between node N₉ (i.e. to a non-inverting input of the second operational amplifier 410₂) and ground.

It should be understood that the embodiment of FIG. 4 is one example implementation of the oscillator portion 402 and that other embodiments may apply. For example, an optical lattice clock (OLC) oscillator configuration or a Wien bridge oscillator configuration may be used instead of the one illustrated in FIG. 4.

Using the configuration presented in FIG. 4, should the processing unit 202 fail to generate a wave signal for each CHUA circuit 104₁, 104₂, . . . , 104_{N}, the oscillator portion 402 may still be operational and enable oscillation within the system 400. It will be appreciated that, in such cases where the processing unit 202 fails to generate the wave signal, the signals output by the CHUA circuits 104₁, 104₂, . . . , 104_{N} may however suffer from low precision. For example, the sinusoidal signals may, in this case, be generated by the synchronization unit 102 with a precision of about 0.01 Hz.

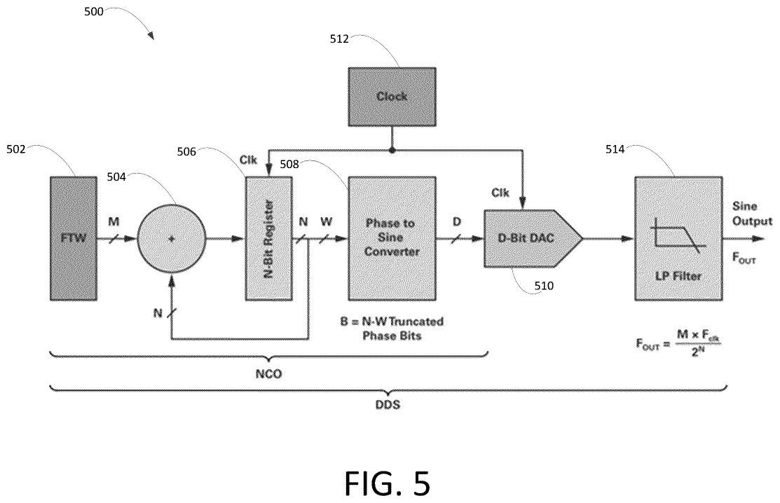

FIG. 5 illustrates another embodiment of the synchronization unit 102 of FIG. 1. In the embodiment of FIG. 5, a Direct Digital Synthesis (DDS) unit 500 is used as the synchronization unit 102. In this embodiment, the DDS unit 500 replaces the processing unit 202. The DDS unit 500 comprises a Frequency-domain Time Windowing (FTW) unit 502, a summation block 504, an N-bit register 506, a phase-to-sine converter 508, a clock 512 (having any suitable clock frequency), a D-bit DAC 510, and a lowpass (LP) filter 514.

The clock 512 is used to drive the N-bit register 506 and the DAC 510. On each clock cycle, the FTW unit 502 stores a digital number (M) which is added (at summation block 504) to a number (N) output by the N-bit register 506. Any suitable values may apply for the numbers M and N, depending on the application. In one embodiment, the value of M is selected in the range from 4 to 20, and the value of N is selected in the range from 24 to 32. The phase truncated output of the N-bit register 506 (i.e. W phase truncated bits) is sent to the phase-to-sine converter (also referred to herein as a “phase converter”) 508 for use in addressing a lookup table that contains the digital amplitude information for one cycle of a sinewave. In one embodiment, the lookup table is a sine lookup table. In other embodiments, a cosine lookup table may be used. Each address in the lookup table corresponds to a phase point on a sinewave, from zero (0) degrees to 360 degrees. By addressing the lookup table, the phase-to-sine converter 508 can map phase information from the N-bit register 506 into a digital amplitude (i.e. map the phase truncated bits to a plurality of digital amplitude values), which is output to the DAC 510 (e.g., as D amplitude truncated bits) and used to drive the DAC 510. In some embodiments, the DAC 510 has a resolution between 2 to 4 bits less than the width of the lookup table. The DAC 510 is configured to generate a periodic signal (e.g., a sinusoidal signal) based on the digital amplitude received from the phase-to-sine converter 508. The DAC output is then provided to the LP filter 514, which provides a filtered sine output. The LP filter 514 operates as an antialiasing filter that filters the DAC output to compensate for the fact that the amplitude response of the DAC output follows a response with zeros at the clock frequency and multiples thereof (a phenomenon referred to as rolloff). The sine output generated by the LP filter 514 (i.e. the filtered output of the DAC 510) is then provided as input to a respective chaotic circuit (reference 104₁, 104₂, . . . , 104_{N} in FIG. 1).

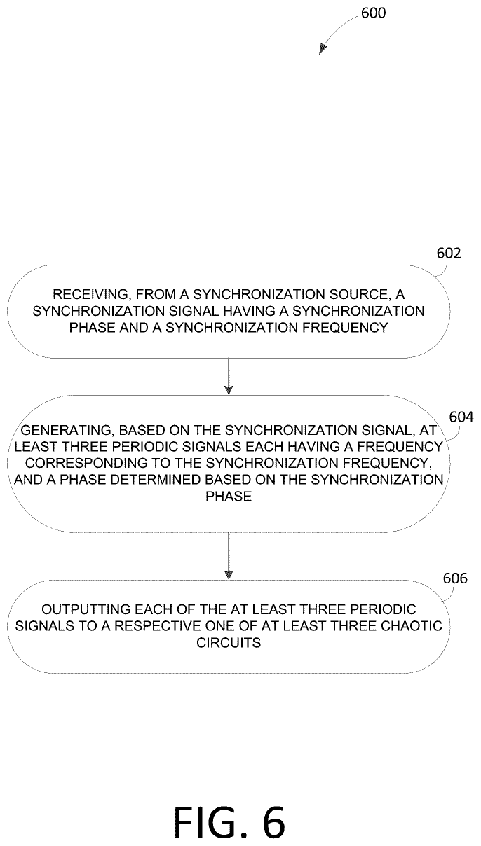

Referring now to FIG. 6, a method 600 for multiphase chaotic synchronization will now be described, in accordance with one embodiment. The method 600 may be performed by the processing unit 202 of FIG. 2A. Step 602 comprises receiving, from a synchronization source, a synchronization signal having a synchronization phase and a synchronization frequency. The synchronization signal may be received from the synchronization source(s) 106 described above with reference to FIG. 1. Step 606 comprises generating, based on the synchronization signal, at least three periodic signals each having a frequency corresponding to the synchronization frequency, and a phase determined based on the first phase. As described herein above, in some embodiments, the phase of each of the at least three periodic signals may be shifted (by a predetermined phase shift amount) relative to the phase of remaining ones of the at least three periodic signals. Step 608 comprises outputting each of the at least three periodic signals to a respective one of at least three chaotic circuits (e.g., CHUA circuits 104₁, 104₂, . . . , 104_{N} of FIG. 1). The periodic signals may then be used by the chaotic circuits to generate control signals that allow to control the operation of at least one electronic device (e.g., electronic device(s) 108 of FIG. 1) electrically coupled to the at least three chaotic circuits, as described herein above. For example, the control signals may cause synchronization of electronic devices (e.g., power inverters) electrically connected in parallel to form a multi-phase system, as described herein above.

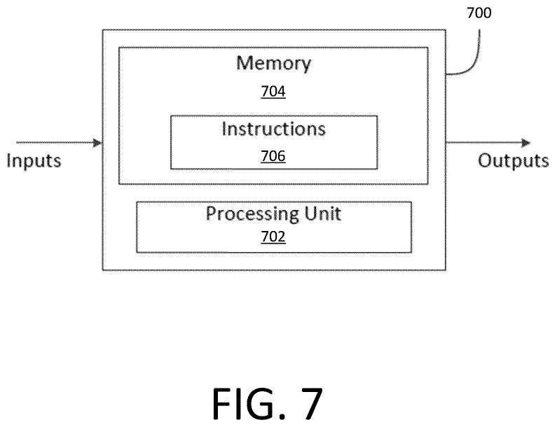

FIG. 7 is a schematic diagram of computing device 700, which may be used to implement at least part of the synchronization unit 102 (e.g., the processing unit 202) and/or method 600 of FIG. 6. The computing device 700 comprises a processing unit 702 and a memory 704 which has stored therein computer-executable instructions 706. The processing unit may 702 may comprise any suitable devices configured to implement the functionality of the method 600 such that instructions 706, when executed by the computing device 700 or other programmable apparatus, may cause the functions/acts/steps performed by method 600 as described herein to be executed. The processing unit 702 may comprise, for example, any type of general-purpose microprocessor or microcontroller, a digital signal processing (DSP) processor, an integrated circuit, a field programmable gate array (FPGA), a reconfigurable processor, a programmable read-only memory (PROM), or any combination thereof.

The memory 704 may comprise any suitable known or other machine-readable storage medium. The memory 704 may comprise non-transitory computer readable storage medium, for example, but not limited to, an electronic, magnetic, optical, electromagnetic, infrared, or semiconductor system, apparatus, or device, or any suitable combination of the foregoing. The memory 704 may include a suitable combination of any type of computer memory that is located either internally or externally to device, for example random-access memory (RAM), read-only memory (ROM), compact disc read-only memory (CDROM), electro-optical memory, magneto-optical memory, erasable programmable read-only memory (EPROM), and electrically erasable programmable read-only memory (EEPROM), Ferroelectric RAM (FRAM) or the like. Memory 704 may comprise any storage means (e.g., devices) suitable for retrievably storing machine-readable instructions 706 executable by the processing unit 702.

Using the systems and methods described herein in which the oscillator circuit of a typical CHUA circuit, which is usually formed by an LC circuit (i.e. an inductance and capacitor connected in parallel) or by a gyrator circuit connected in parallel with a capacitor, may be replaced with a programmable phase and frequency oscillator can improve the precision of the resulting chaotic synchronization. The systems and methods described herein may also prove stable in temperature and source voltage variation contrary to conventional implementations that use a gyrator circuit which are subject to such variation and exhibit a higher frequency of oscillator change (i.e. lower stability). While the gyrator may cause variation in the signal, the nature of the chaotic circuit enables autoregulation between the nodes of the circuit. In addition, using the systems and methods described herein may allow to reduce overall complexity and lower implementation costs due to the use of the stable and high precision phase-shift configurable oscillator.

Furthermore, the systems and methods described herein offer stability in temperature and source voltage variation. Typical LC implementation using gyrators are subject to large variations and the frequency of the oscillator may thus vary. For instance, for a 60 Hz implementation, the variation may be in the order of 0.1 Hz. For the same implementation, the use of a microprocessor to control or replace the gyrator may allow to achieve a stability in the ppm range of about 1×10⁻⁶ Hz.

The above description is meant to be exemplary only, and one skilled in the art will recognize that changes may be made to the embodiments described without departing from the scope of the invention disclosed. Still other modifications which fall within the scope of the present invention will be apparent to those skilled in the art, in light of a review of this disclosure.

Various aspects of the systems and methods described herein may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments. Although particular embodiments have been shown and described, it will be apparent to those skilled in the art that changes and modifications may be made without departing from this invention in its broader aspects. The scope of the following claims should not be limited by the embodiments set forth in the examples, but should be given the broadest reasonable interpretation consistent with the description as a whole.

1. A system for multiphase chaotic synchronization, the system comprising:
a processor; and
a non-transitory computer-readable medium having stored thereon program instructions executable by the processor for:
receiving, from a synchronization source coupled to an input of the processor, a synchronization signal having a synchronization phase and a synchronization frequency associated therewith;
generating, based on the synchronization signal, at least three periodic signals each having a frequency corresponding to the synchronization frequency, and a phase determined based on the synchronization phase; and
outputting each of the at least three periodic signals to a respective one of at least three chaotic circuits for use in controlling an operation of at least one electronic device electrically coupled to the at least three chaotic circuits.

2. The system of claim 1, wherein the program instructions are executable by the processor for generating the at least three periodic signals having a same phase corresponding to the synchronization phase.

3. The system of claim 1, wherein the program instructions are executable by the processor for generating the at least three periodic signals with the phase of a given periodic signal corresponding to the synchronization phase, and the phase of each remaining periodic signal being shifted relative to the phase of the given periodic signal and relative to the phase of other periodic signals.

4. The system of claim 1, wherein the program instructions are executable by the processor for generating the at least three periodic signals, comprising:
querying a lookup table with the synchronization signal, the lookup table containing a plurality of digital amplitude values for at least one cycle of a periodic signal; and
using at least three digital-to-analog converters to convert the plurality of digital amplitude values into at least three analog signals each representative of a respective one of the at least three periodic signals.

5. The system of claim 1, wherein each of the at least three chaotic circuits comprises a chaotic portion only, further wherein the said processor is electrically coupled to the chaotic portion of each of the at least three chaotic circuits.

6. The system of claim 1, wherein each of the at least three chaotic circuits comprises an oscillator portion connected to a chaotic portion, further wherein the processor is electrically coupled to the oscillator portion of each of the at least three chaotic circuits.

7. The system of claim 1, wherein the program instructions are further executable by the processor for executing, based on a selection input, a holdover function to select the synchronization source among a plurality of synchronization sources coupled to the input of the processor.

8. The system of claim 7, wherein the program instructions are further executable by the processor for detecting a failure of the plurality of synchronization sources and for using a reference signal as the synchronization signal in response to detecting the failure, the reference signal being provided by an oscillator coupled to the input of the processor.

9. The system of claim 7, wherein the plurality of synchronization sources comprises at least one of an external synchronization source remote from the processor, a grid synchronization source associated with a power utility network, and a Global Positioning System (GPS) module synchronization source.

10. The system of claim 1, wherein the oscillator is a crystal oscillator.

11. The system of claim 1, wherein the at least one electronic device comprising at least three electronic devices electrically connected in parallel, further wherein each of the at least three periodic signals is output to the respective one of the at least three chaotic circuits for causing the at least three chaotic circuits to output control signals to the at least three electronic devices for synchronizing the operation of the at least three electronic devices.

12. A method for multiphase chaotic synchronization, the method comprising:
at a computing device:
receiving a synchronization signal having a synchronization phase and a synchronization frequency associated therewith;
generating, based on the synchronization signal, at least three periodic signals each having a frequency corresponding to the synchronization frequency, and a phase determined based on the synchronization phase; and
outputting each of the at least three periodic signals to a respective one of at least three chaotic circuits for use in controlling an operation of at least one electronic device electrically coupled to the at least three chaotic circuits.

13. The method of claim 12, wherein the at least three periodic signals are generated with the same phase corresponding to the synchronization phase.

14. The method of claim 12, wherein the phase of a given periodic signal corresponds to the synchronization phase, and the phase of each remaining periodic signal being shifted relative to the phase of the given periodic signal and relative to the phase of other periodic signals.

15. The method of claim 12, wherein generating the at least three periodic signals comprises:
querying a lookup table with the synchronization signal, the lookup table containing a plurality of digital amplitude values for at least one complete cycle of a periodic signal; and
converting the plurality of digital amplitude values into at least three analog signals each representative of a respective one of the at least three periodic signals.

16. The method of claim 12, further comprising receiving a selection input and executing, based on the selection input, a holdover function to select the synchronization source among a plurality of synchronization sources coupled to the input of the processor.

17. The method of claim 16, further comprising detecting a failure of the plurality of synchronization sources and using a reference signal as the synchronization signal in response to detecting the failure, the reference signal being provided by an oscillator.

18. The method of claim 12, wherein the at least one electronic device comprising at least three electronic devices electrically connected in parallel, further wherein each of the at least three periodic signals is output to the respective one of the at least three chaotic circuits for causing the at least three chaotic circuits to output control signals to the at least three electronic devices for synchronizing the operation of the at least three electronic devices.

19. A system for multiphase chaotic synchronization, the system comprising:
a register configured to generate a plurality of phase truncated bits;
a phase converter coupled to the register and configured to receive therefrom the plurality of phase truncated bits and to map the plurality of phase truncated bits to a plurality of digital amplitude values; and
a digital-to-analog converter coupled to the phase converter and configured to receive therefrom the plurality of digital amplitude values and to generate, based on the plurality of digital amplitude values, a periodic signal to be provided to a respective one of at least three chaotic circuits for use in controlling an operation of at least one electronic device electrically coupled to the at least three chaotic circuits.

20. The system of claim 19, further comprising a filter coupled to the digital-to-analog converter and to the at least three chaotic circuits, the filter configured to filter the periodic signal for generating a filtered signal and to output the filtered signal to the respective chaotic circuit.
